(19) United States
(12) Patent Application Publication
(10) Pub. No.: US 2009/0314326 A1
(43) Pub. Date: Dec. 24, 2009

(54) PHOTOVOLTAIC MODULE

(75) Inventors: Ivan Saha, Chennai (IN); Manoj Rout, Chennai (IN)

Correspondence Address: DARBY & DARBY P.C., P.O. BOX 770, Church Street Station, New York, NY, 10008-0770, US

(73) Assignee: MOSER BAER PHOTOVOLTAIC LIMITED, Chennai (IN)

(21) Appl. No.: 12/177,974

(22) Filed: Jul. 23, 2008

(30) Foreign Application Priority Data
Jun. 24, 2008 (IN) 2008/CHE/007141

(51) Int. Cl. H01L 31/042; B05C 11/00; H01L 31/18; H01L 21/304

(52) U.S. Cl. 136/246; 118/44; 29/890.033

(57) ABSTRACT

Embodiments relate to an apparatus for generating electricity from solar energy, said apparatus having a base substrate; one or more photovoltaic strips arranged over said base substrate, wherein spaces are formed in between adjacent photovoltaic strips; a plurality of optical vees for concentrating solar energy over said photovoltaic strips, said optical vees being placed in said spaces between said photovoltaic strips, said optical vees comprising a reflective layer or surface, such that rays incident on said reflective layer or surface are reflected towards said photovoltaic strips; and a transparent member positioned over said optical vees, wherein said base substrate, said photovoltaic strips, said optical vees and said transparent member form said apparatus in an integrated manner. Other embodiments include systems for generating electricity using the photovoltaic module. Yet other embodiments relate to methods of manufacturing the photovoltaic module and systems for generating electricity using the photovoltaic module.

### CROSS REFERENCE TO RELATED APPLICATIONS

This application claims the benefit of Indian Patent Application Number 2008/CHE/007141, filed on Jun. 24, 2008, which is hereby incorporated by reference in its entirety.

### BACKGROUND

The present invention relates, in general, to photovoltaic modules. More specifically, the present invention relates to a method for fabricating a photovoltaic module.

Photovoltaic cells are large area semiconductor diodes that convert incident solar energy into electrical energy. Photovoltaic cells are often made of silicon wafers. The photovoltaic cells are combined in series and/or parallel to form photovoltaic modules.

In order to increase the power output and reduce the cost of the photovoltaic modules, silicon is partly replaced by cheap plastic reflective/refractive optics to concentrate Sun's radiation in smaller area. In one such approach, high concentrators are employed to concentrate the incident radiation over the photovoltaic cells. High concentrators require direct solar rays in order to work appropriately hence call for solar tracking. Moreover, high concentration leads to generation of excessive heat in the cells and, therefore requires a suitable cooling mechanism to minimize damage and efficiency reduction. However, low concentrators even work in diffused sun light.

In addition, various techniques are used to increase the efficiency of the photovoltaic modules. Reflective coatings may be used with concentrators to reflect the sun rays over the photovoltaic cells, while anti-reflective coatings may be used to minimize wastage of solar energy during transmission.

Existing photovoltaic modules use silicon wafers as a major component. This makes these photovoltaic modules expensive and difficult to manufacture efficiently on a large scale. However, various techniques are employed by replacing silicon with cheap plastic reflective/refractive optics in order to increase the power output and reduce cost of the photovoltaic modules. However, conventional photovoltaic modules are not economical, due to higher rejections during manufacturing/quality control processes, low efficiencies owing to requirement of precise assembly process.

In light of the foregoing discussion, there is a need for a photovoltaic module (and a fabrication method and system thereof) that is suitable for mass manufacturing, has lower cost, has ease of manufacturing compared to conventional low concentrator photovoltaic modules and requires lesser amount of silicon, while still achieving a desired power output.

### SUMMARY

An object of the present invention is to provide a photovoltaic module (and a fabrication method and system thereof) that is suitable for mass manufacturing.

Another object of the present invention is to provide the photovoltaic module that has lower cost. The photovoltaic module should be fabricated with lesser amount of silicon compared to conventional low concentrator photovoltaic modules, while still achieving the same power output.

Yet another object of the present invention is to provide the photovoltaic module that has higher efficiency compared to conventional low concentrator photovoltaic modules. This is to maximize the power output of the photovoltaic module.

Still another object of the present invention is to provide the photovoltaic module that has ease of manufacturing compared to conventional low concentrator photovoltaic modules.

Embodiments of the present invention provide a photovoltaic module for generating electricity from solar energy. The photovoltaic module includes a base substrate for providing support to the photovoltaic module. One or more photovoltaic strips are arranged over the base substrate in a predefined manner. Spaces are formed between adjacent photovoltaic strips. The predefined manner may, for example, be a series and/or parallel arrangement, such that electrical output is maximized. The photovoltaic strips are connected through one or more conductors in series and/or parallel. In an embodiment of the present invention, the photovoltaic strips may be formed by dicing a semiconductor wafer.

A plurality of optical vees is placed in the spaces between the photovoltaic strips. The optical vees are capable of concentrating the solar energy over the photovoltaic strips. The optical vees have a reflective layer, such that sun rays incident on the reflective layer are reflected towards the photovoltaic strips. When the reflected sun rays fall on the photovoltaic strips, electricity is generated by the photoelectric effect. These optical vees may, for example, be made of glass, plastics, polymeric materials, Ethyl vinyl acetate (EVA), thermoplastic poly-urethane (TPU), poly vinyl butyral (PVB), silicone, acrylics, polycarbonates, metals, metallic alloys, metal compounds, and ceramics. In accordance with an embodiment of the present invention, the optical vees comprise a reflection-enhancing layer to enhance the reflectivity of the optical vees.

In an embodiment of the present invention, the optical vees are formed by polishing surfaces of a prism of a reflective material. In this case, the optical vees are solid. In another embodiment of the present invention, the optical vees are formed by polishing a sheet of a reflective material, which may be bent in a desired shape of the optical vees. In such a case, the optical vees are hollow and the optical vees may, for example, be V-shaped or triangular in cross-section. In yet another embodiment of the present invention, the optical vees are made of a foil of a reflective material sandwiched between two moldable plastic sheets. The sandwiched foil is bent in a desired shape of the optical vees. As the moldable sheets are electrically non-conductive, optical vees can be placed over the sandwiched foil. In such a case, the optical vees are hollow and the optical vees may, for example, be V-shaped or triangular in cross-section. In still another embodiment of the present invention, the reflective layer is formed by coating the optical vees with a reflective material.

A transparent member is positioned over the optical vees. In accordance with an embodiment of the present invention, the transparent member is sealed with the base substrate. In accordance with an embodiment of the present invention, the base substrate, the photovoltaic strips, the optical vees and the transparent member form the photovoltaic module in an integrated manner. In accordance with an embodiment of the present invention, the transparent member is coated with an anti-reflective coating to reduce loss of solar energy incident on the photovoltaic module.

The fabrication of the photovoltaic module involves the similar processes and machines that are required to fabricate conventional low concentrator photovoltaic modules. Therefore, the method of fabrication of the photovoltaic module is easy, quick and cost-effective.

Moreover, the photovoltaic module provides maximized outputs, at appropriate configurations of the photovoltaic strips and appropriate levels of concentration. The optical vees provide concentration ratios between 5:1 and 1.5:1, and concentrate solar energy onto the photovoltaic strips. Therefore, the photovoltaic module requires lesser amount of semiconductor material to generate same electrical output compared to conventional low concentrator photovoltaic modules.

### BRIEF DESCRIPTION OF DRAWINGS

Embodiments of the present invention will hereinafter be described in conjunction with the appended drawings provided to illustrate and not to limit the present invention, wherein like designations denote like elements, and in which:

FIG. 1 illustrates a blown-up view of a photovoltaic module, in accordance with an embodiment of the present invention;

FIG. 2 illustrates a cross-sectional view of the photovoltaic module, in accordance with an embodiment of the present invention;

FIG. 3 illustrates how photovoltaic strips are connected through a plurality of conductors, in accordance with an embodiment of the present invention;

FIG. 4 illustrates an arrangement of a photovoltaic strip between solid optical vees, in accordance with an embodiment of the present invention;

FIG. 5 illustrates an arrangement of a photovoltaic strip between hollow optical vees, in accordance with another embodiment of the present invention;

FIG. 6 illustrates an optical vee, in accordance with yet another embodiment of the present invention;

FIG. 7 illustrates an arrangement of a photovoltaic strip between solid optical vees, in accordance with still another embodiment of the present invention;

FIG. 8 is a perspective view of a string configuration of photovoltaic strips, in accordance with an embodiment of the present invention;

FIG. 9 is a perspective view illustrating optical vees placed with the string configuration, in accordance with an embodiment of the present invention;

FIG. 10 is a perspective view illustrating a lay-up of a transparent member over the optical vees, in accordance with an embodiment of the present invention;

FIG. 11 is a blown-up view of a photovoltaic module, in accordance with an embodiment of the present invention;

FIG. 12 illustrates a system for manufacturing a photovoltaic module, in accordance with an embodiment of the present invention;

FIG. 13 is a flow diagram illustrating a method for fabricating a photovoltaic module, in accordance with an embodiment of the present invention;

FIG. 14 is a flow diagram illustrating a method for fabricating a photovoltaic module, in accordance with another embodiment of the present invention;

FIG. 15A illustrates a method of fabricating optical vees, in accordance with an embodiment of the present invention;

FIG. 15B illustrates a method of fabricating optical vees, in accordance with another embodiment of the present invention;

FIG. 15C illustrates a method of fabricating optical vees, in accordance with yet another embodiment of the present invention;

FIG. 15D illustrates a method of fabricating optical vees, in accordance with still another embodiment of the present invention;

FIG. 16 illustrates a system for generating electricity from solar energy, in accordance with an embodiment of the present invention;

FIG. 17 illustrates a system for generating electricity from solar energy, in accordance with another embodiment of the present invention;

FIG. 18 illustrates a method for manufacturing a system for generating electricity from solar energy, in accordance with an embodiment of the present invention;

FIG. 19 illustrates a method for manufacturing a system for generating electricity from solar energy, in accordance with another embodiment of the present invention;

FIG. 20 illustrates how the level of concentration can be varied, in accordance with an embodiment of the present invention;

FIG. 21 illustrates how the level of concentration can be varied, in accordance with an embodiment of the present invention;

FIG. 22 is a cross-sectional view illustrating how electromagnetic radiation is concentrated over photovoltaic strips, in accordance with an embodiment of the present invention;

FIG. 23 is a schematic diagram illustrating a configuration of one or more photovoltaic strips, in accordance with another embodiment of the present invention; and

FIG. 24 illustrates a simulation of the output of a photovoltaic strip of size 125 mm×12 mm, in accordance with an embodiment of the present invention.

### DETAILED DESCRIPTION

As used in the specification and claims, the singular forms “a”, “an” and “the” include plural references unless the context clearly dictates otherwise. For example, the term “a photovoltaic module” may include a plurality of photovoltaic modules unless the context clearly dictates otherwise. A term having “-containing” such as “metal-containing” contains a metal but is open to other substances, but need not contain any other substance other than a metal.

Embodiments of the present invention provide a method, system and apparatus for generating electricity from solar energy, and a method and system for manufacturing a photovoltaic module. In the description herein for embodiments of the present invention, numerous specific details are provided, such as examples of components and/or mechanisms, to provide a thorough understanding of embodiments of the present invention. One skilled in the relevant art will recognize, however, that an embodiment of the present invention can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments of the present invention.

### Glossary

Photovoltaic module: A photovoltaic module is a packaged interconnected assembly of photovoltaic cells, which converts solar energy into electricity by the photovoltaic effect.
Integrated manner: In terms of the apparatus (photovoltaic module), it means that the electrically connected photovoltaic strips and the concentrator elements form an integrated and functional unit only at the module level. Any sub-part of the apparatus is not a functionally independent unit. In terms of the method of manufacturing in an integrated manner, it means that the assembly of the apparatus (photovoltaic module) consisting of photovoltaic strips, optical vees, and transparent member on the base substrate is carried out in one integrated sequence of operations without making functionally separate sub-units or sub-assemblies.
Base substrate: A base substrate is a term used to describe the base member of photovoltaic module on which photovoltaic strips are placed.
Photovoltaic strip: A photovoltaic strip is a part of semiconductor wafer used in the fabrication of photovoltaic module.
Optical vee: An optical vee is a member with at least two surfaces arranged in the shape of an ‘inverted-V’.
Polymeric material: A polymeric material is a substance composed of molecules with large molecular mass composed of repeating structural units, or monomers, connected by covalent chemical bonds.
Conductors: Elements for electrically connecting photovoltaic strips to form a circuit.
Space: Space is the area between the adjacent photovoltaic strips.
Cavity: Cavity is three-dimensional region formed between adjacent optical vees and the photovoltaic strip that is placed between the adjacent optical vees.
Medium boundary: Medium boundary is a boundary between two mediums. For example, a medium boundary is formed at a boundary between glass and air.
Laminate: Laminate is an entire assembly of the photovoltaic strip, base substrate, optical vee and transparent member joined by the polymeric material.
Reflection-enhancing layer: Reflection-enhancing layer is a layer that enhances the reflectivity of a surface.
Transparent member: Transparent member is an optically clear member placed over the photovoltaic module to seal and protect the photovoltaic module from environmental damage.
Anti-reflective coating: Anti-reflective coating is a coating over the transparent member to reduce loss of solar energy incident on the photovoltaic module.
Dicer: A dicer is for dicing a semiconductor wafer to form the photovoltaic strips.
Stringer: A stringer is for connecting the photovoltaic strips through one or more conductors.
Strip-arranger: A strip arranger is for arranging the photovoltaic strips over the base substrate.
Optical-vee placer: An optical-vee placer is for placing the optical vees in the spaces between the photovoltaic strips.
Molder: A molder is for molding the polymeric material to form the optical vee.
Depositer: A depositer is for depositing the reflective material over the optical vees to form the reflective layer.
Tool: A tool is for machining solid blocks of the reflective material to form the optical vee.
Polisher: A polisher is for polishing surface of the reflective layer.
Bending Unit: A bending unit is for bending sheet/foil to form the optical vee.
Sandwiching Unit: A sandwiching unit is for sandwiching a foil of the reflective material between two plastic sheets to form a sandwiched foil.
Positioning unit: A positioning unit is for positioning the transparent member over the optical vees.
Sealing unit: A sealing unit is for sealing the transparent member with the base substrate.
Power-consuming unit: A power-consuming unit is for consuming and/or storing the power generated by the photovoltaic module.
AC Load: AC Load is a device that operates on Alternating Current (AC).
DC Load: DC Load is a device that operates on Direct Current (DC).
Charge controller: A charge controller controls the amount of charge consumed by the power-consuming unit.
Inverter: An inverter converts the electricity from a first form to a second form. For example, it converts electricity from AC to DC or vice-versa.

Embodiments of the photovoltaic module include a base substrate (also referred as backpanel), for example, made of anodized aluminum for providing a support to the photovoltaic module. Photovoltaic strips are arranged over the base substrate in strings with series and/or parallel arrangement, such that electrical output is maximized. The photovoltaic strips are arranged with spaces in between adjacent photovoltaic strips. A plurality of optical vees are placed in the spaces between the photovoltaic strips and bonded to the aluminum backpanel. The optical vees comprise a reflective layer or surface. A plurality of trapezoidal shaped cavities is formed between adjacent optical vees. The trapezoidal shaped cavities have air/vacuum enclosed within them.

An optically clear, low iron content glass cover sheet could be placed on the optical vees. The glass cover sheet is sealed with the base substrate along a peripheral region of the base substrate, thereby forming an embodiment of the photovoltaic module.

When light falls on the photovoltaic module, it is reflected at the reflective layer or surface and gets concentrated according to the geometric concentration ratio defined by the entry and exit aperture of the trapezoidal shaped cavity.

Embodiments of the photovoltaic module include a base substrate (also referred as backpanel), for example, made of anodized aluminum for providing a support to the photovoltaic module. Photovoltaic strips are arranged over the base substrate in strings with series and/or parallel arrangement, such that electrical output is maximized. The photovoltaic strips are arranged with spaces in between adjacent photovoltaic strips. A plurality of reflecting optical vees are placed in the spaces between the photovoltaic strips and bonded to the aluminum backpanel. The optical vees can be solid (like a glass prism) or hollow inside (like two mirrors forming a vee) with a reflective metal coating on the inside walls of the hollow optical vees. A plurality of trapezoidal shaped cavities is formed between adjacent optical vees. The trapezoidal shaped cavities have air/vacuum enclosed within them. An optically clear, low iron content glass cover sheet is generally placed on the optical vees. The cover glass and the aluminum backpanel are sealed at their edges using silicon to form an enclosed photovoltaic module that seals the inside of the module from moisture. When light falls on the module, it enters the cover glass and is reflected at a reflecting layer or surface of the optical vee (which could be a surface of a solid glass vee prism or a mirror-like inside surface of a hollow glass vee) and gets concentrated according to the geometric concentration ratio defined by the entry and exit aperture of the trapezoidal cavity.

The photovoltaic module includes a base substrate for providing support to the photovoltaic module. One or more photovoltaic strips are arranged over the base substrate in a predefined manner. The predefined manner may, for example, be a series and/or parallel arrangement, such that electrical output is maximized. For example, the photovoltaic strips may be rectangular in shape, and may be arranged substantially parallel to each other with spaces in between two adjacent photovoltaic strips.

In an embodiment of the present invention, the photovoltaic strips may be formed by dicing a semiconductor wafer. In another example, the photovoltaic strips may be circular or arc-like in shape, and may be arranged in the form of concentric circles. The photovoltaic strips may also be square, triangular, or any other shape, in accordance with a desired configuration. The photovoltaic strips are connected through one or more conductors in series and/or parallel.

A plurality of optical vees is placed in the spaces between the photovoltaic strips. The optical vees are capable of concentrating the solar energy over the photovoltaic strips. The optical vees are inverted-V-shaped in cross-section, in accordance with an embodiment of the present invention. In accordance with another embodiment of the present invention, the optical vees are compound-parabolic-shaped in cross-section. The optical vees have a reflective layer or surface, such that sun rays incident on the reflective layer or surface are reflected towards the photovoltaic strips. When the reflected sun rays fall on the photovoltaic strips, electricity is generated by the photoelectric effect. These optical vees may, for example, be made of glass, plastics, polymeric materials, Ethyl vinyl acetate (EVA), thermoplastic poly-urethane (TPU), poly vinyl butyral (PVB), silicone, acrylics, polycarbonates, metals, metallic alloys, metal compounds, and ceramics. In accordance with an embodiment of the present invention, the optical vees comprise a reflection-enhancing layer to enhance the reflectivity of the optical vees.

In an embodiment of the present invention, the optical vees are formed by polishing surfaces of a prism of a reflective material. In this case, the optical vees are solid. In another embodiment of the present invention, the optical vees are formed by polishing a sheet of a reflective material, which may be bent in a desired shape of the optical vees. In such a case, the optical vees are hollow and the optical vees may, for example, be V-shaped or triangular in cross-section. In yet another embodiment of the present invention, the optical vees are made of a foil of a reflective material sandwiched between two moldable plastic sheets. The sandwiched foil is bent in a desired shape of the optical vees. In such a case, the optical vees are hollow and the optical vees may, for example, be V-shaped or triangular in cross-section. In still another embodiment of the present invention, the reflective layer is formed by coating the optical vees with a reflective material.

A transparent member is positioned over the optical vees. The transparent member protects the photovoltaic strips and the optical vees from environmental damage. In accordance with an embodiment of the present invention, the transparent member is sealed with the base substrate along a peripheral region of the base substrate. In accordance with an embodiment of the present invention, the base substrate, the photovoltaic strips, the optical vees and the transparent member form the photovoltaic module in an integrated manner. In accordance with an embodiment of the present invention, the transparent member is coated with an anti-reflective coating to reduce loss of solar energy incident on the photovoltaic module.

The acceptance angle of the photovoltaic module is chosen, such that rays normally incident on the optical vees are reflected towards the photovoltaic strips with minimal optical losses. Tracking mechanisms may be used to change the position of the photovoltaic module, in order to keep the rays normally incident upon the photovoltaic module while the sun moves across the sky. This further enhances the power output of the photovoltaic module.

The photovoltaic module can be used in various applications. For example, an array of photovoltaic modules may be used to generate electricity on a large scale for grid power supply. In another example, photovoltaic modules may be used to generate electricity on a small scale for home/office use. Alternatively, photovoltaic modules may be used to generate electricity for stand-alone electrical devices, such as automobiles and spacecraft. Details of these applications have been provided in conjunction with drawings below.

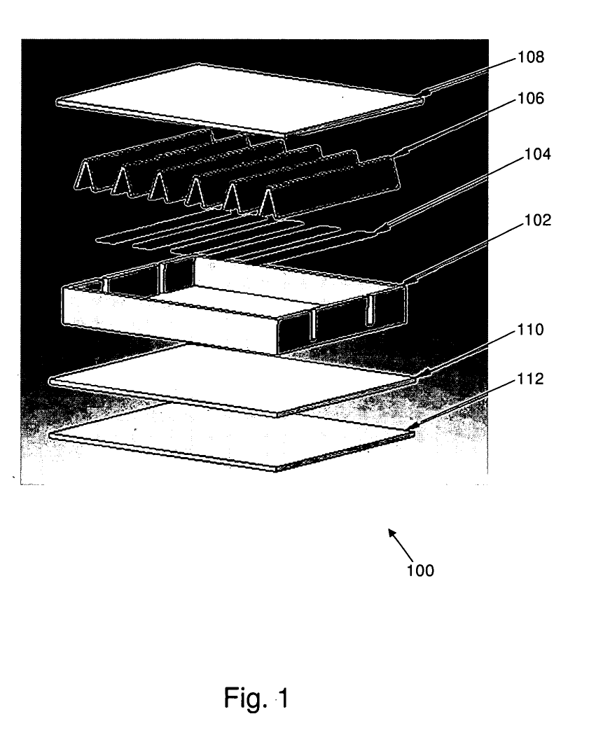

FIG. 1 illustrates a blown-up view of a photovoltaic module 100, in accordance with an embodiment of the present invention. Photovoltaic module 100 includes a base substrate 102, one or more photovoltaic strips 104, a plurality of optical vees 106, a transparent member 108, a laminate 110 and a supporting substrate 112.

Base substrate 102 provides a base for photovoltaic module 100. With reference to FIG. 1, base substrate 102 is rectangular in shape. Base substrate 102 can be made of any material that is tolerant to moisture, Ultra Violet (UV) radiation, abrasion, and natural temperature variations. Examples of such materials include, but not limited to, aluminium, steel, plastics and suitable polycarbonates. In addition, base substrate 102 may, for example, be made of plastics with metal coating or plastics with high thermal conductivity fillers. Examples of such fillers include, but are not limited to, boron nitride (BN), aluminium oxide, (Al₂O₃), and metals. The base substrate has an electrically insulated top surface. For example, base substrate is coated with a layer of electrically insulating material, such as anodized aluminium.

Photovoltaic strips 104 are arranged over base substrate 102. With reference to FIG. 1, photovoltaic strips 104 are rectangular in shape and are arranged parallel to each other with spaces in between two adjacent photovoltaic strips. Photovoltaic strips 104 are made of a semiconductor material. Examples of semiconductors include, but are not limited to, monocrystalline silicon (c-Si), polycrystalline or multicrystalline silicon (poly-Si or mc-Si), ribbon silicon, cadmium telluride (CdTe), copper-indium diselenide (CuInSe₂), combinations of III-V and II-VI elements in the periodic table that have photovoltaic effect, copper indium/gallium diselenide (ClGS), gallium arsenide (GaAs), germanium (Ge), gallium indium phosphide (GaInP₂), organic semiconductors such as polymers and small-molecule compounds like polyphenylene vinylene, copper phthalocyanine and carbon fullerenes, amorphous silicon (a-Si or a-Si:H), protocrystalline silicon, and nanocrystalline silicon (nc-Si or nc-Si:H). When electromagnetic radiation falls over photovoltaic strips 104, electron-hole pairs are formed within the semiconductor. These electron- hole pairs act as charge carriers, and thus, produce electrical energy.

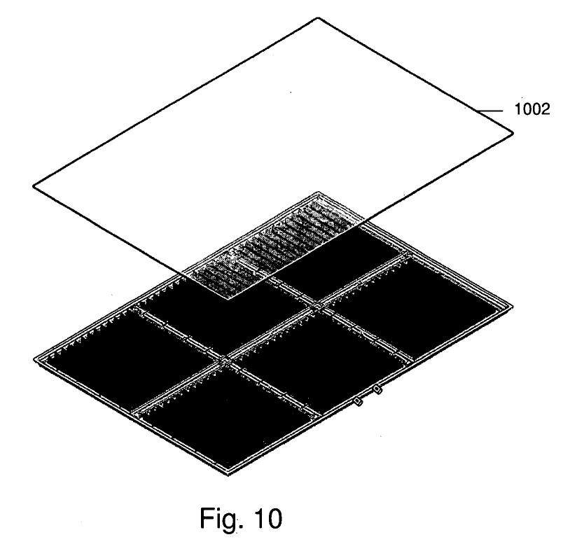

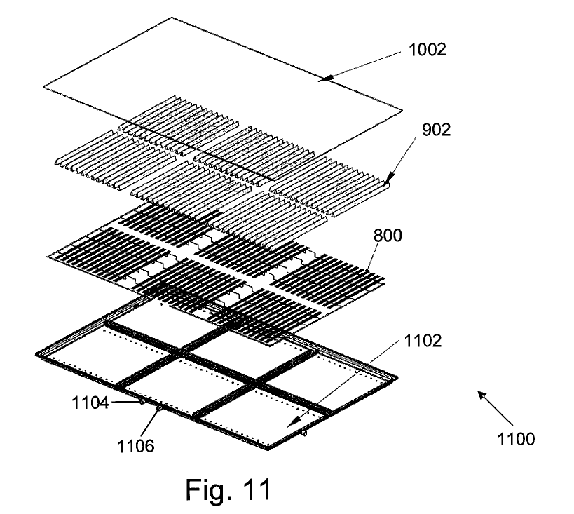

With reference to FIG. 1, optical vees 106 are placed in the spaces between photovoltaic strips 104 and at the outermost sides. Optical vees 106 concentrate the electromagnetic radiation over photovoltaic strips 104. The level of concentration may be varied depending on the shape and size of optical vees 106. Details of various levels of concentration have been provided in conjunction with FIGS. 10 and 11.

Transparent member 108 is positioned over optical vees 106. Transparent member 108 protects optical vees 106 and photovoltaic strips 104 from environmental damage, while allowing electromagnetic radiation falling on its surface to pass through. With reference to FIG. 1, transparent member 108 is flat rectangular in shape. In other cases, transparent member 108 may have any desired shape, such as a curved shape. The refractive index of transparent member 108 can be varied, while minimizing the reflectivity of transparent member 108, to increase the efficiency of concentration. Transparent member 108 is coated with an anti-reflective coating on its top and bottom surfaces, so that no reflection occurs at medium boundaries between air and transparent member 108.

In accordance with an embodiment of the present invention, laminate 110 is formed by a laminate material to encapsulate photovoltaic strips 104 and optical vees 106. Laminate 110 holds photovoltaic module 100 and its components together, and protects photovoltaic module 100 against moisture, abrasion, and natural temperature variations. The process of lamination is performed at a prescribed temperature and/or pressure in a vacuum environment using a laminator. The vacuum environment ensures that no air bubbles are formed within the laminate. In order to avoid heat sinking during lamination, supporting substrate 112 is used as a heat barrier, and removed later.

The laminate material can be any material that is tolerant to moisture, UV radiation, abrasion, and natural temperature variations. Examples of the laminate material include, but are not limited to, EVA, silicone and other synthetic resins.

As the seal at the edge of photovoltaic module 100 so formed may remain non-hermetic, an additional step of framing photovoltaic module 100 may be performed. This can be accomplished by mechanically attaching a frame to laminate 110.

In an embodiment of the present invention, the fabrication of photovoltaic module 100 is done by using a high speed robotic assembly. The robotic assembly includes one or more robotic arms, which are employed for performing various processes during the fabrication. In one example, a robotic arm may be used to connect photovoltaic strips 104 over base substrate 102. In another example, the placement of optical vees 106 in between photovoltaic strips 104 may be done with another robotic arm. The processes of wire bonding and die attachment in fabrication of photovoltaic module 100 may also be performed with the robotic arms.

It is to be understood that the specific designation for photovoltaic module 100 and its components is for the convenience of the reader and is not to be construed as limiting photovoltaic module 100 and its components to a specific number, size, shape, type, material, or arrangement.

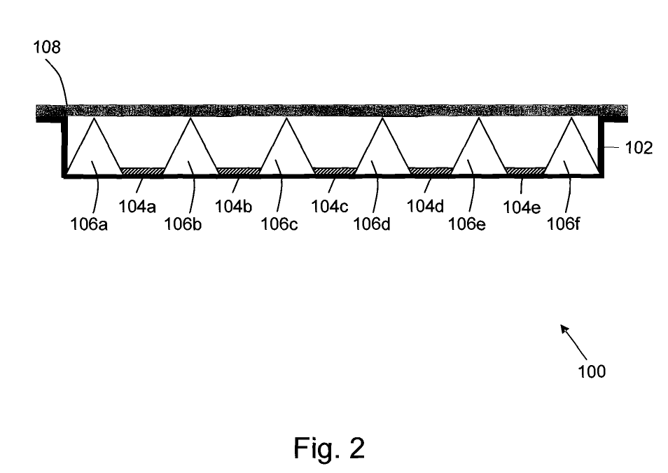

FIG. 2 illustrates a cross-sectional view of photovoltaic module 100, in accordance with an embodiment of the present invention. In FIG. 2, photovoltaic strips 104 are shown as a photovoltaic strip 104a, a photovoltaic strip 104b, a photovoltaic strip 104c, a photovoltaic strip 104d, and a photovoltaic strip 104e. Optical vees 106 are shown as an optical vee 106a, an optical vee 106b, an optical vee 106c, an optical vee 106d, an optical vee 106e, and an optical vee 106f. With reference to FIG. 2, optical vee 106a and optical vee 106b concentrate solar energy towards photovoltaic strip 104a, optical vee 106b and optical vee 106c concentrate solar energy towards photovoltaic strip 104b, and so on. With reference to FIG. 2, optical vees 106 are solid. Transparent member 108 is coated with an anti-reflective coating and is placed over base substrate 102 enclosing photovoltaic strip 104a, photovoltaic strip 104b, photovoltaic strip 104c, photovoltaic strip 104d, photovoltaic strip 104e, optical vee 106a, optical vee 106b, optical vee 106c, optical vee 106d, optical vee 106e, and optical vee 106f. It should be noted that the enclosure of base substrate 102 is not limited to the number of elements shown in the figure.

A single photovoltaic strip and a single optical vee are collectively termed as a ‘low concentrator unit’. A plurality of such low concentrator units may be combined together to form a photovoltaic module, in accordance with an embodiment of the present invention.

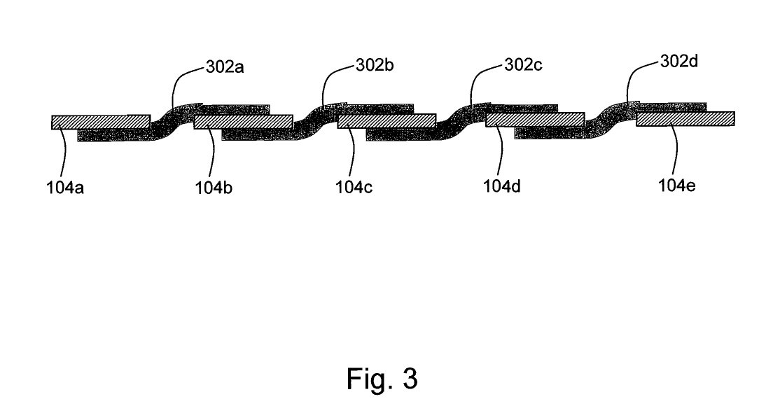

FIG. 3 illustrates how photovoltaic strips 104 are connected through a plurality of conductors, in accordance with an embodiment of the present invention. With reference to FIG. 3, photovoltaic strips 104 are connected in series. In such a configuration, the p-side of photovoltaic strip 104a is connected to the n-side of photovoltaic strip 104b using a conductor 302a, the p-side of photovoltaic strip 104b is connected to the n-side of photovoltaic strip 104c using a conductor 302b, the p-side of photovoltaic strip 104c is connected to the n-side of photovoltaic strip 104d using a conductor 502c, and the p-side of photovoltaic strip 104d is connected to the n-side of photovoltaic strip 104e using a conductor 302d.

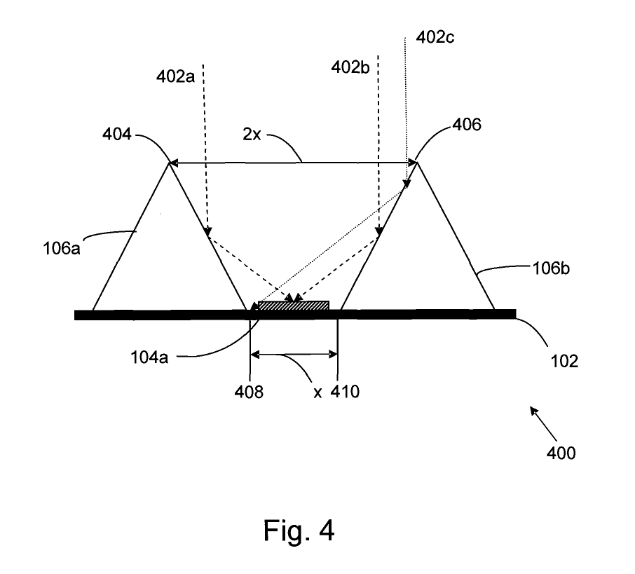

FIG. 4 illustrates an arrangement 600 of photovoltaic strip 104a between solid optical vees 106a and 306b, in accordance with an embodiment of the present invention. With reference to FIG. 4, optical vees 106 are solid. Optical vees 106 are formed by machining and polishing solid blocks of a reflective material, such as a metal, metallic alloy, or a metal compound. Examples of such reflective material include, but are not limited to, aluminium, silver, nickel, and steel. As described earlier, photovoltaic strips 306 are made of a semi-conductor material. Photovoltaic strip 104a is placed in between optical vee 106a and optical vee 106b, such that gaps are left between optical vee 106a and photovoltaic strip 104a, and between photovoltaic strip 104a and optical vee 106b. These gaps are left to avoid short circuiting between optical vees 106 and photovoltaic strips 104.

A ray 402a, incident on a side of optical vee 106a, undergoes reflection and falls over photovoltaic strip 104a. Similarly, a ray 402b, incident on a side of optical vee 106b, undergoes reflection and falls over photovoltaic strip 104a. However, a ray 402c, incident on the side of optical vee 106b, undergoes reflection and falls away from photovoltaic strip 104a. In order to concentrate such a ray over photovoltaic strip 104a, the upper portion of the sides of optical vees 106 may be curved in as a concave. This reduces loss of solar energy.

An entry area, formed between an upper end 404 of optical vee 106a and an upper end 406 of optical vee 106b, has a length of ‘x’ units. An exit area, formed between a lower end 408 of optical vee 106a and a lower end 410 of optical vee 106b, has a length of ‘2x’ units. The entry area is defined as an area through which rays enter, while the exit area is defined as an area through which the rays exit towards photovoltaic strips 104. The level of concentration is measured by the ratio of the entry area and the exit area. With reference to FIG. 4, the level of concentration is equal to 2. The level of concentration may vary between 1.5 and 5. Since the power output of photovoltaic module 100 depends on the level of concentration, the power output doubles.

As mentioned above, the level of concentration may also be varied by varying the shape and size of optical vees 106. Heat sinkers and fin radiators may be used to avoid heat sinking in case of higher levels of concentration.

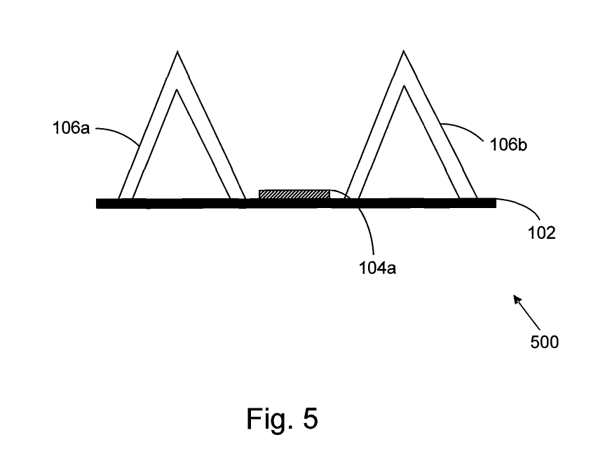

FIG. 5 illustrates an arrangement 500 of photovoltaic strip 104a between hollow optical vees 106a and 106b, in accordance with another embodiment of the present invention. With reference to FIG. 5, optical vees 106 are hollow with air or vacuum inside. Optical vees 106 are formed by polishing and bending a sheet of a reflective material, such as a metal, metallic alloy, or a metal compound, so as to form the shape. Optical vees 106 may, for example, be hollow V-shaped or hollow triangular-shaped in cross-section. Photovoltaic strip 104a is placed in between optical vee 106a and optical vee 106b, such that gaps are left between optical vee 106a and photovoltaic strip 104a, and between photovoltaic strip 104a and optical vee 106b. These gaps are left to avoid short circuiting between optical vees 106 and photovoltaic strips 104.

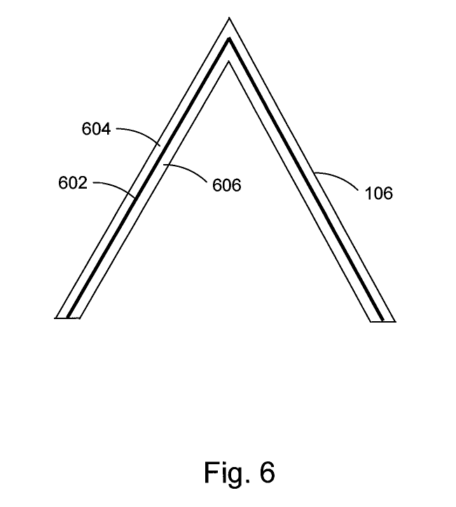

FIG. 6 illustrates an optical vee 306, in accordance with yet another embodiment of the present invention. Optical vee 306 is made of a foil 602 of a reflective material sandwiched between two moldable sheets 604 and 606. Sandwiched foil 602 is bent to form an inverted-V-shape in cross-section. In such a case, optical vee 306 is hollow in cross-section. As the outer layers of sandwiched foil 602 are electrically insulated, optical vees 106 made of such sandwiched foil may be placed in contact with photovoltaic strips 104. No short-circuiting occurs in such an arrangement.

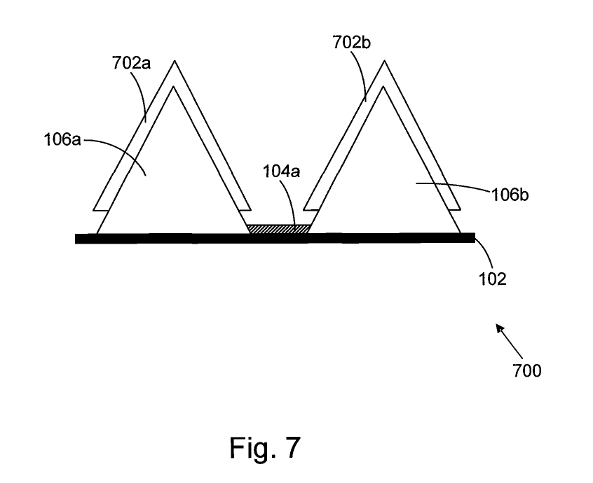

FIG. 7 illustrates an arrangement 700 of photovoltaic strip 104a between solid optical vees 106a and 106b, in accordance with still another embodiment of the present invention. With reference to FIG. 7, optical vees 106 are solid. Optical vees 106 may, for example, be made of glass, plastics, EVA, silicone, TPU, acrylics, polycarbonates, metals, metallic alloys and ceramics. Optical vee 106a and optical vee 106b are coated with a reflective layer 702a and a reflective layer 702b, respectively. Reflective layer 702a and reflective layer 702b may, for example, be made of reflective materials, such as aluminium, silver, nickel or other suitable metals, metallic alloys, and metal compounds.

With reference to FIG. 7, photovoltaic strip 104a is placed in between optical vee 106a and optical vee 106b, such that no gaps are left between optical vee 106a and photovoltaic strip 104a and between optical vee 106b and photovoltaic strip 104a. While reflective layer 702a and reflective layer 702b do not touch photovoltaic strip 104a, so as to avoid short circuiting between them.

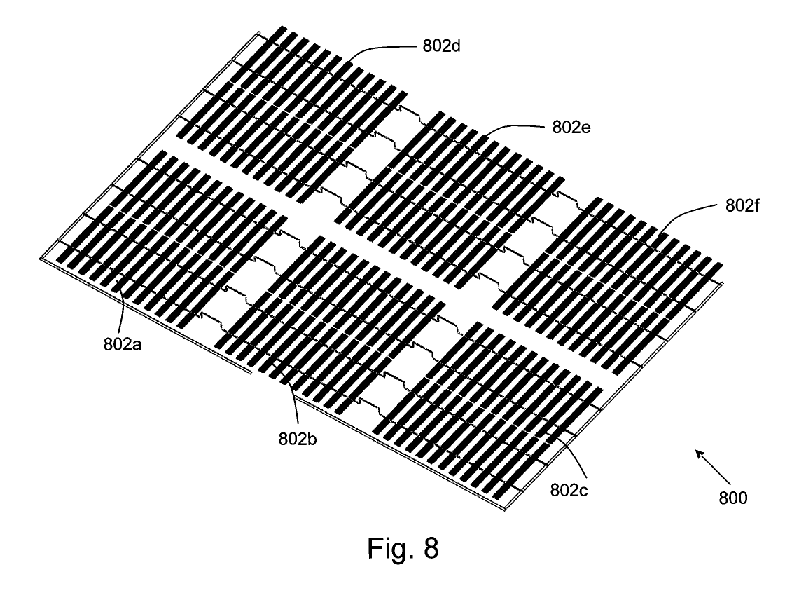

FIG. 8 is a perspective view of a string configuration 800 of photovoltaic strips, in accordance with an embodiment of the present invention. A string 802a, a string 802b, a string 802c, a string 802d, a string 802e and a string 802f are formed by stringing one or more photovoltaic strips in series. String 802a, string 802b and string 802c are combined in series. Similarly, string 802d, string 802e and string 802f are combined in series. These two series configurations are then combined in parallel. String configuration 800 is arranged over a base substrate, in accordance with an embodiment of the present invention.

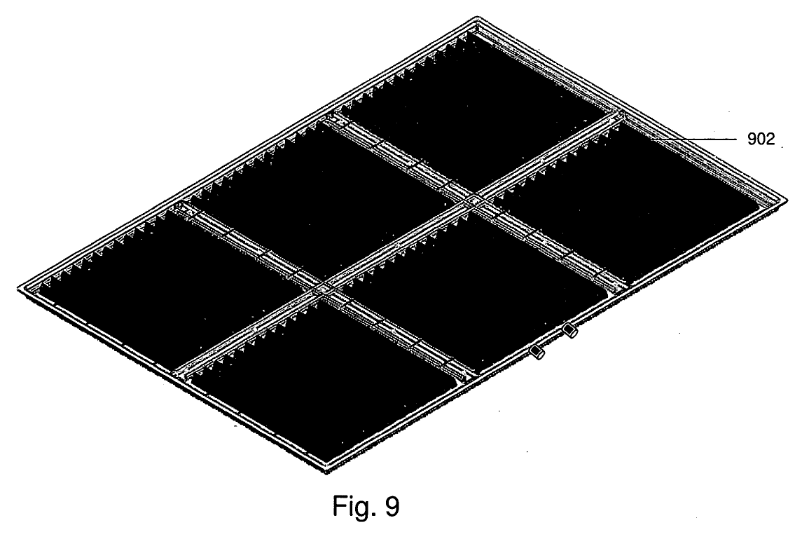

FIG. 9 is a perspective view illustrating optical vees 902 placed with string configuration 800, in accordance with an embodiment of the present invention. Optical vees 902 are placed in between the photovoltaic strips consecutively.

FIG. 10 is a perspective view illustrating a lay-up of a transparent member 1002 over optical vees 902, in accordance with an embodiment of the present invention.

FIG. 11 is a blown-up view of a photovoltaic module 1100, in accordance with an embodiment of the present invention. With reference to FIG. 11, string configuration 800 is arranged over a base substrate 1102. Optical vees 902 are aligned and placed in the spaces between photovoltaic strips of string configuration 800. Transparent member 1002 is positioned over optical vees 902.

Base substrate 1102 includes a positive terminal 1104 and a negative terminal 1106 for drawing electricity from photovoltaic module 1100, in accordance with an embodiment of the present invention. In various embodiments of the present invention, positive terminal 1104 and negative terminal 1106 may be present at another location on base substrate 1102.

It is to be understood that the specific designation for the photovoltaic module and its components as shown in FIGS. 8-11 is for the convenience of the reader and is not to be construed as limiting the photovoltaic module and its components to a specific number, size, shape, type, material, or arrangement.

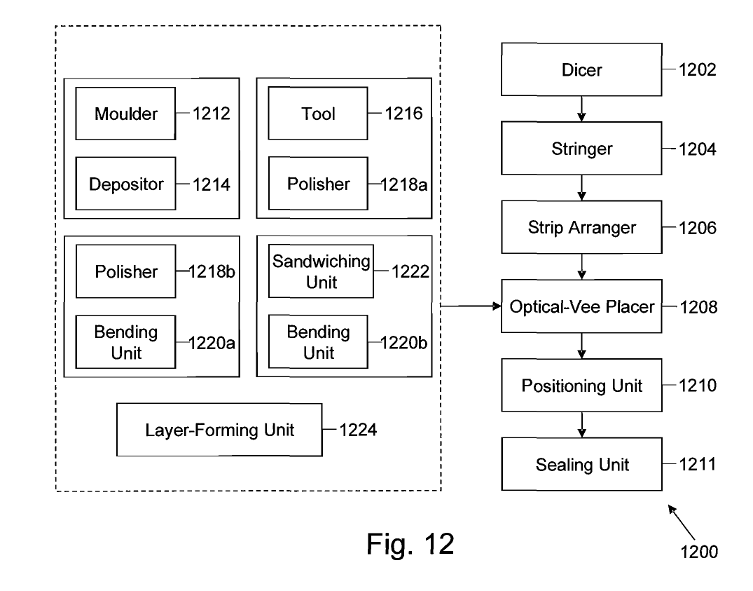

FIG. 12 illustrates a system 1200 for manufacturing a photovoltaic module, in accordance with an embodiment of the present invention. System 1200 includes a dicer 1202, a stringer 1204, a strip arranger 1206, an optical-vee placer 1208, a positioning unit 1210, and a sealing unit 1211. System 1200 also includes a molder 1212, a depositor 1214, a tool 1216, a polisher 1221a, a polisher 1221b, a bending unit 1220a, a sandwiching unit 1222, a bending unit 1220b, and a layer-forming unit 1224.

Dicer 1202 dices a semiconductor wafer to form a plurality of photovoltaic strips. Dicer 1202 may, for example, be a mechanical saw or a laser dicer. Laser dicers dice a semiconductor wafer from its p-side using a laser source. This provides a clean cut without any burrs, and involves minimal material damage.

Stringer 1204 connects the photovoltaic strips through one or more conductors in a predefined manner, such that one or more strings of photovoltaic strips are formed. The photovoltaic strips are connected such that spaces are formed in between adjacent photovoltaic strips. Stringer 1204 may, for example, perform soldering using a manual process, a semi-automatic process, or a high-speed robotic assembly. Solder-coated copper strips may, for example, be used as the conductors. Alternatively, stringer 1204 may perform wire bonding using a high-speed robotic assembly.

Strip arranger 1206 arranges the strings of photovoltaic strips over a base substrate. Strip arranger 1206 may, for example, be a pick-and-place unit that picks the strings of photovoltaic strips, and aligns and places them as per a specified arrangement.

In accordance with another embodiment of the present invention, strip arranger 1206 arranges individual photovoltaic strips over a base substrate, and stringer 1204 connects the photovoltaic strips with each other over the base substrate. In such a case, strip arranger 1206 may, for example, be a pick-and-place unit that picks photovoltaic strips, and aligns and places them as per a specified arrangement.

Optical-vee placer 1208 places a plurality of optical vees in spaces between the photovoltaic strips. Optical-vee placer 1208 may, for example, be a pick-and-place unit that picks optical vees, and aligns and places them as per the specified arrangement. The optical vees may be fabricated in different ways. In accordance with an embodiment of the present invention, molder 1212 molds a polymeric material to form the optical vees, and depositor 1214 deposits a reflective material over the optical vees to form a reflective layer. Molder 1212 may, for example, perform injection molding to mold optical vees of a desired shape. Optical vees may, for example, be inverted-V-shaped, and may be either hollow or solid. Depositor 1214 may, for example, perform a suitable Physical Vapour Deposition (PVD) process, such as a sputter deposition process.

In accordance with another embodiment of the present invention, tool 1216 machines solid blocks of a reflective material to form the optical vees, and polisher 1221a polishes surfaces of the machined solid blocks to form a reflective surface. Tool 1216 may, for example, be a lathe machine.

In accordance with yet another embodiment of the present invention, polisher 1221b polishes a sheet of a reflective material to form a reflective surface, and bending unit 1220a bends the sheet to form at least one of said optical vees. Bending unit 1220a may, for example, perform an automatic process of bending the sheet in a desired shape of optical vees. Polisher 1221a and polisher 1221b may either be parts of a polishing unit, or be the same unit.

In accordance with still another embodiment of the present invention, sandwiching unit 1222 sandwiches a foil of a reflective material between two sheets to form a sandwiched foil, and bending unit 1220b bends the sandwiched foil to form at least one of said optical vees. The sheets may, for example, be made of any material that is an electrical insulator and is suitable for bending. Examples of such material include, but are not limited to, polymeric materials, silicone, EVA, TPU, PVB, and plastics. The sheets may be optically transparent, as desired. Bending unit 1220b may, for example, perform an automatic process of bending the sandwiched foil in a desired shape of optical vees. Bending unit 1220a and bending unit 1220b may be the same unit.

As the outer layers of the sandwiched foil are electrically insulated, optical vees made of such sandwiched foil may be placed in contact with the photovoltaic strips. No short-circuiting occurs in such an arrangement.

Layer-forming unit 1224 forms a reflection-enhancing layer over the optical vees to enhance the reflectivity of the optical vees, in accordance with an embodiment of the present invention.

With reference to FIG. 12, positioning unit 1210 positions a transparent member over the optical vees. Positioning unit 1210 may, for example, be a pick-and-place unit that picks the transparent member, and aligns and places it as per the specified arrangement. Thereafter, sealing unit 1211 seals the transparent member with the base substrate. In accordance with an embodiment of the present invention, the sealing is performed at the periphery. This may be accomplished by a resistive heating process using sealing rollers that melts a solder preform and forms a hermetic seal. Alternatively, the seal may be formed by a needle-dispensed epoxy, gasket sealing, glass frit, or EVA. In such a case, the seal so formed is non-hermetic, and an additional step of framing the photovoltaic module may be performed. This can be accomplished by mechanically attaching a frame to the photovoltaic module. The frame may be made of a metal or a metallic alloy. Aluminum may be used for this purpose, as it is cheaper and lighter than other metals and metallic alloys.

In accordance with an embodiment of the present invention, the base substrate, the photovoltaic strips, the optical vees and the transparent member form the photovoltaic module in an integrated manner.

Various embodiments of the present invention provide an apparatus for generating electricity from solar energy. The apparatus includes supporting means for providing support to the apparatus, converting means for converting solar energy into electrical energy, means for connecting the converting means in a predefined manner, concentrating means for concentrating solar energy over the converting means, and transparent means for sealing the supporting means, the converting means and the concentrating means. The converting means are arranged over the supporting means with spaces in between adjacent converting means. The concentrating means are placed in the spaces between the converting means. These concentrating means include a reflective layer or surface, such that rays incident on the reflective layer or surface are reflected towards the converting means. The concentrating means may be either hollow or solid.

The transparent means is positioned over the concentrating means. The supporting means, the converting means, the concentrating means and the transparent means form the apparatus in an integrated manner. The transparent means is sealed with the supporting means. The transparent means is coated with an anti-reflective coating to reduce loss of solar energy incident on the apparatus, in accordance with an embodiment of the present invention.

Examples of the supporting means include, but are not limited to, base substrate 102 and base substrate 1102. Examples of the converting means include, but are not limited to, photovoltaic strips 104, and string configuration 800. Examples of the means for connecting include, but are not limited to, conductors 302a-d. Examples of the concentrating means include, but are not limited to, optical vees 106 and optical vees 902. Examples of the transparent means include, but are not limited to, transparent member 108 and transparent member 1002.

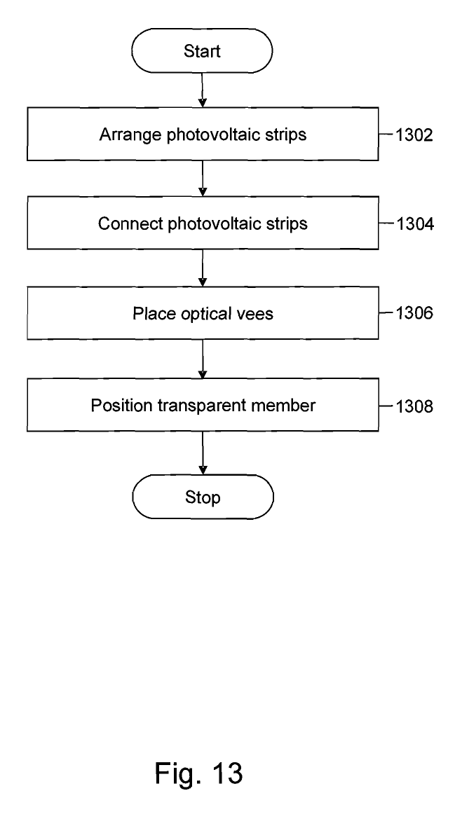

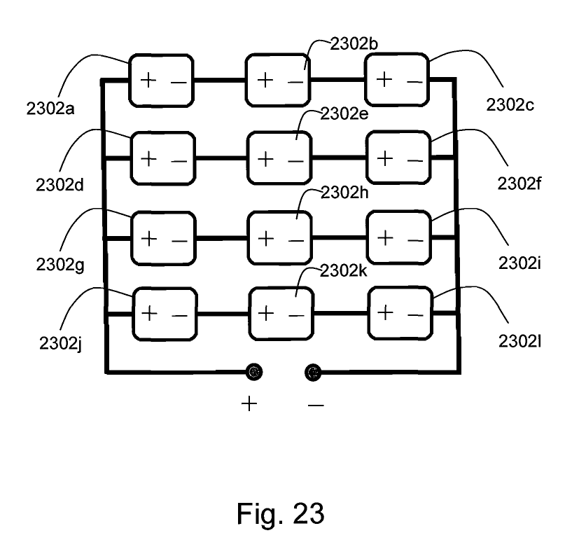

FIG. 13 is a flow diagram illustrating a method for fabricating a photovoltaic module, in accordance with an embodiment of the present invention. At step 1302, one or more photovoltaic strips are arranged over a base substrate in a predefined manner. The predefined manner may, for example, be a series and/or parallel arrangement, such that electrical output is maximized. For example, the photovoltaic strips may be rectangular in shape, and may be arranged parallel to each other with spaces in between two adjacent photovoltaic strips. Alternatively, the photovoltaic strips may be circular or arc-like in shape, and may be arranged in the form of concentric circles. The photovoltaic strips may also be square, triangular, or any other shape, in accordance with a desired configuration. The photovoltaic strips are capable of converting solar energy into electrical energy. At step 1304, the photovoltaic strips are connected through one or more conductors. The photovoltaic strips may be connected in series and/or parallel. Details of various configurations of photovoltaic strips have been provided in conjunction with FIGS. 23 and 8.

At step 1306, a plurality of optical vees is placed in the spaces between the photovoltaic strips. For example, the optical vees may be placed in a manner that each photovoltaic strip has two adjacent optical vees. The optical vees are inverted-V-shaped in cross-section, in accordance with an embodiment of the present invention. In accordance with another embodiment of the present invention, the optical vees are compound-parabolic-shaped in cross-section. The optical vees may be either hollow or solid. These optical vees may, for example, be made of glass, plastics, polymeric materials, Ethyl vinyl acetate (EVA), thermoplastic poly-urethane (TPU), poly vinyl butyral (PVB), silicone, acrylics, polycarbonates, metals, metallic alloys, metal compounds, and ceramics. The optical vees are capable of concentrating solar energy over the photovoltaic strips. The optical vees have a reflective layer or surface, such that rays incident on the reflective layer or surface are reflected towards the photovoltaic strips.

At step 1308, a transparent member is positioned over the optical vees. The transparent member protects the photovoltaic strips and the optical vees from environmental damage. Examples of the transparent member include, but are not limited to, glass, plastics, polymeric materials and EVA. The transparent member may, for example, be a toughened glass with low iron content, or be made of a polymeric material which is non-UV-degradable.

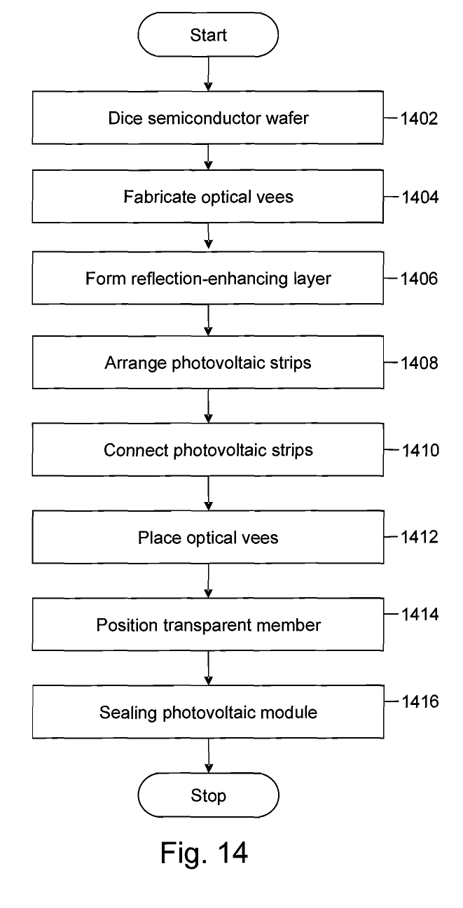

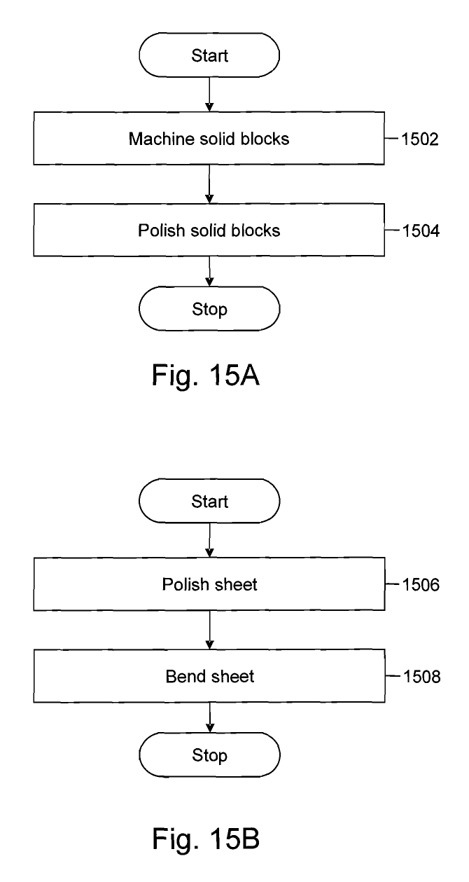

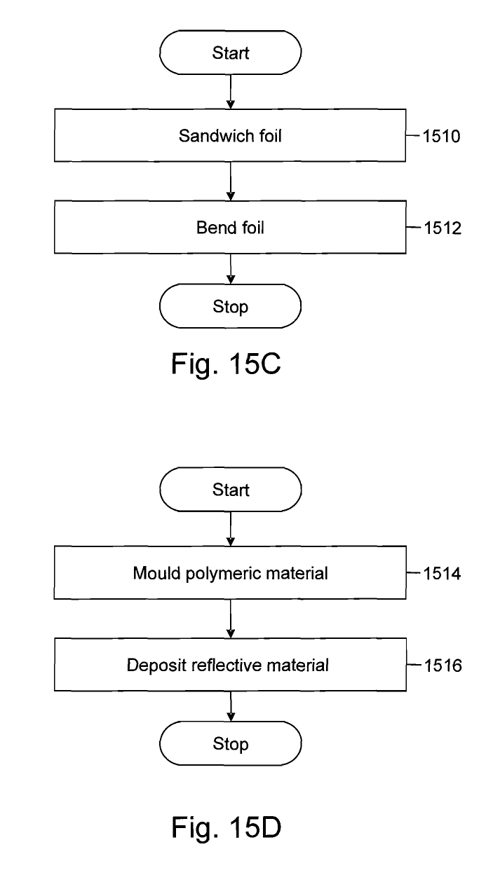

FIG. 14 is a flow diagram illustrating a method for fabricating a photovoltaic module, in accordance with another embodiment of the present invention. At step 1402, a semiconductor wafer is diced to form one or more photovoltaic strips. This can be accomplished by mechanical sawing or laser dicing. In laser dicing, a semiconductor wafer is diced from its p-side using a laser source. This provides a clean cut without any burrs, and involves minimal material damage. At step 1404, optical vees are fabricated. Optical vees may be fabricated in various ways. Details of the same have been provided in conjunction with FIG. 15A-D. At step 1406, a reflection-enhancing layer is formed over the optical vees to enhance the reflectivity of the optical vees.

At step 1408, one or more photovoltaic strips are arranged over a base substrate in a predefined manner. The predefined manner may, for example, be a series and/or parallel arrangement, such that electrical output is maximized. At step 1410, the photovoltaic strips are connected through one or more conductors. This may be accomplished by manual soldering or by soldering using a high-speed soldering machine. Solder-coated copper strips may, for example, be used as the conductors. As mentioned above, the photovoltaic strips may be connected in series and/or parallel. Details of various configurations of photovoltaic strips have been provided in conjunction with FIGS. 23 and 8.

At step 1412, a plurality of optical vees is placed in the spaces between the photovoltaic strips, such that solar energy is concentrated over the optical vees. As mentioned above, the optical vees have a reflective layer or surface, and may be either hollow or solid. The optical vees may, for example, be made of glass, plastics, polymeric materials, EVA, TPU, PVB, silicone, acrylics, polycarbonates, metals, metallic alloys, metal compounds and ceramics.

At step 1414, a transparent member is coated with an anti-reflective coating to reduce loss of solar energy incident on the photovoltaic module. Therefore, no reflection occurs at medium boundaries between air and the transparent member. The anti-reflective coating may, for example, be made of silicon nitride, an oxide of silicon, or an oxide of titanium.

At step 1416, the photovoltaic strips and the optical vees are sealed with the transparent member. The transparent member is positioned over the optical vees. The transparent member protects the photovoltaic strips and the optical vees from environmental damage, while allowing electromagnetic radiation falling on its surface to pass through it. The transparent member may, for example, be made of glass, plastics, polymeric materials and EVA. The transparent member may, for example, be a toughened glass with low iron content, or be made of a suitable polymeric material which is non-UV-degradable.

In an embodiment of the present invention, the transparent member is sealed along a peripheral region of the base substrate, using a suitable material. This may be accomplished by a resistive heating process using sealing rollers that melts a solder preform and forms a hermetic seal. The seal may also be formed by a needle-dispensed epoxy, gasket sealing, glass frit, or EVA. As the seal at the edge of the photovoltaic module so formed may remain non-hermetic, an additional step of framing the photovoltaic module may be performed. This can be accomplished by mechanically attaching a frame to the photovoltaic module. The frame may be made of a metal or a metallic alloy. Aluminium may be used for this purpose, as it is cheaper and lighter than other metals and metallic alloys.

FIG. 15A-D illustrate various methods of fabricating optical vees. FIG. 15A illustrates a method of fabricating optical vees, in accordance with an embodiment of the present invention. At step 1502, solid blocks of a reflective material are machined to form the optical vees. At step 1504, surfaces of each solid block are polished to form a reflective surface.

FIG. 15B illustrates a method of fabricating optical vees, in accordance with another embodiment of the present invention. At step 1506, a sheet of a reflective material is polished to form a reflective surface. At step 1508, the polished sheet is bent to form at least one of the optical vees.

FIG. 15C illustrates a method of fabricating optical vees, in accordance with yet another embodiment of the present invention. At step 1510, a foil of a reflective material is sandwiched between two sheets to form a sandwiched foil. The sandwiched foil forms the reflective layer. At step 1512, the sandwiched foil is bent to form at least one of the optical vees.

FIG. 15D illustrates a method of fabricating optical vees, in accordance with still another embodiment of the present invention. At step 1514, a polymeric material is molded to form the optical vees. At step 1516, a reflective material is deposited over the optical vees to form a reflective layer.

The reflective material can be any metal, metallic alloy, or metal compound that is resistant to damage due to moisture and natural temperature variations, and has high reflectivity. Examples of such reflective material include, but are not limited to, aluminium, silver, nickel and steel. Aluminium may be used as a reflective material, as it is cheaper than other materials. However, in certain cases, silver may be used, as its reflectivity is sufficiently higher than aluminium to offset the difference in cost.

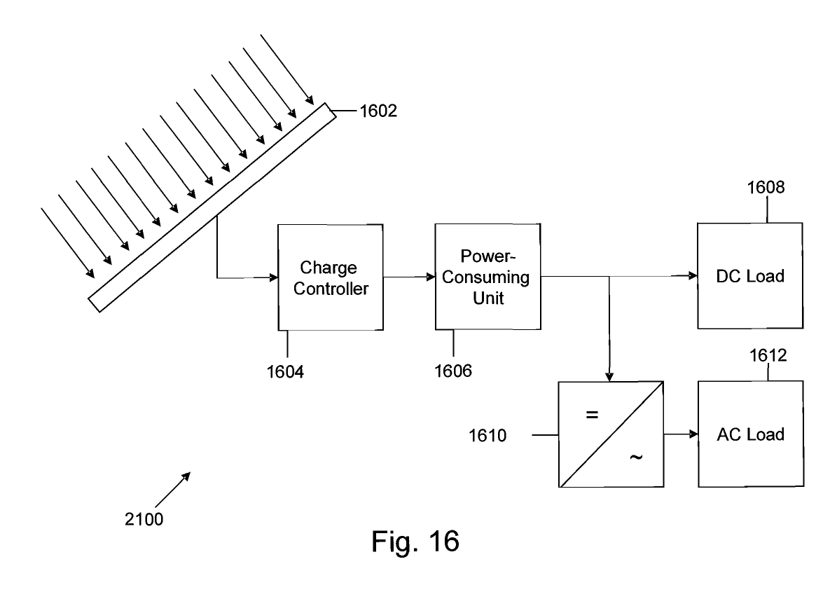

FIG. 16 illustrates a system 1600 for generating electricity from solar energy, in accordance with an embodiment of the present invention. System 1600 includes a photovoltaic module 1602, a charge controller 1604, a power-consuming unit 1606, a Direct Current (DC) load 1608, an inverter 1610 and an Alternating Current (AC) load 1612.

Photovoltaic module 1602 generates electricity from the solar energy that falls on photovoltaic module 1602. Photovoltaic module 1602 is similar to photovoltaic module 100. Power-consuming unit 1606 is connected with photovoltaic module 1602. Power-consuming unit 1606 consumes and/or stores the charge generated by photovoltaic module 1602. Power-consuming unit 1606 may, for example, be a battery.

In an embodiment of the present invention, charge controller 1604 is connected with photovoltaic module 1602 and power-consuming unit 1606. Charge controller 1604 controls the amount of charge consumed in power-consuming unit 2106. For example, if the amount of charge stored in power-consuming unit 1606 exceeds a first threshold, charge controller 1604 discontinues further charging of power-consuming unit 2106. Similarly, if the amount of charge stored in power-consuming unit 1606 falls below a second threshold, charge controller 1604 reinitiates charging of power-consuming unit 1606. In an embodiment of the present invention, the first threshold and the second threshold lie between the maximum and the minimum capacity of power-consuming unit 1606.

Power-consuming unit 1606 produces electricity in a first form. In an embodiment of the present invention, the first form is a DC that can be utilized by DC load 1608. DC load 1608 may, for example, be a device that operates on DC. In another embodiment of the present invention, the first form is an AC that can be utilized by AC load 1612. AC load 1612 may, for example, be a device that operates on AC.

Inverter 1610 is connected with power-consuming unit 1606. Inverter 1610 converts electricity from the first form to a second form, as required. The second form may be either DC or AC. Consider, for example, that the first form is DC, and a device requires electricity in the second form, that is, AC. Inverter 1610 converts DC into AC.

System 1600 may be implemented at a roof top of a building, for home or office use. Alternatively, system 1600 may be implemented for use with stand-alone electrical devices, such as automobiles and spacecraft.

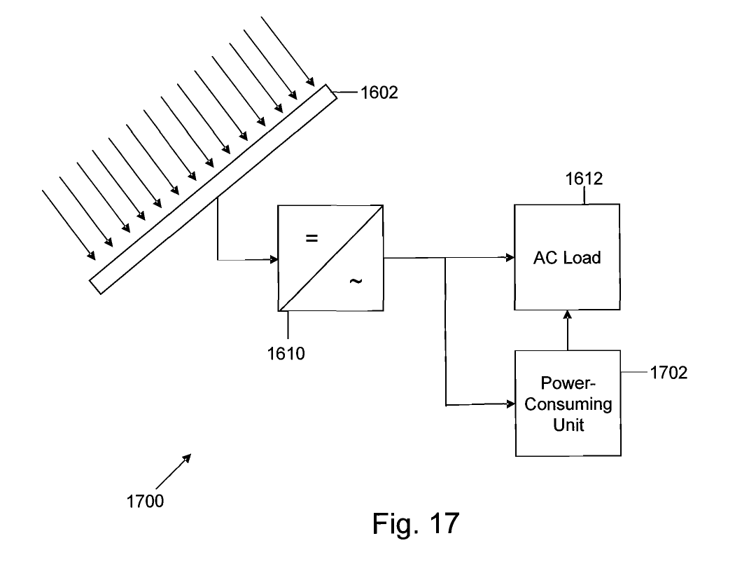

FIG. 17 illustrates a system 1700 for generating electricity from solar energy, in accordance with another embodiment of the present invention. System 1700 includes photovoltaic module 1602, inverter 1610, AC load 1612 and a power-consuming unit 1702.

As mentioned above, inverter 1610 converts electricity generated by photovoltaic module 1602 from the first form to the second form. With reference to FIG. 17, electricity in the second form is utilized by power-consuming unit 1702. Power-consuming unit 1702 may, for example, be a utility grid. For example, an array of photovoltaic modules 1702 may be used to generate electricity on a large scale for grid power supply.

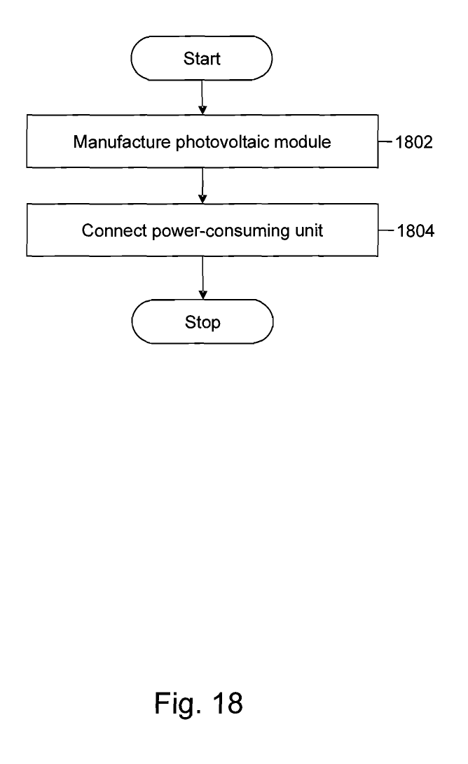

FIG. 18 illustrates a method for manufacturing a system for generating electricity from solar energy, in accordance with an embodiment of the present invention.

At step 1802, a photovoltaic module is manufactured as described in FIGS. 1, 2, 12, 13, 14, and 15A-D. The photovoltaic module may, for example, be photovoltaic module 100 or photovoltaic module 1602. At step 1804, a power-consuming unit is connected to the photovoltaic module. The power-consuming unit consumes the charge generated by the photovoltaic module. The power-consuming unit may either be a battery or a utility grid.

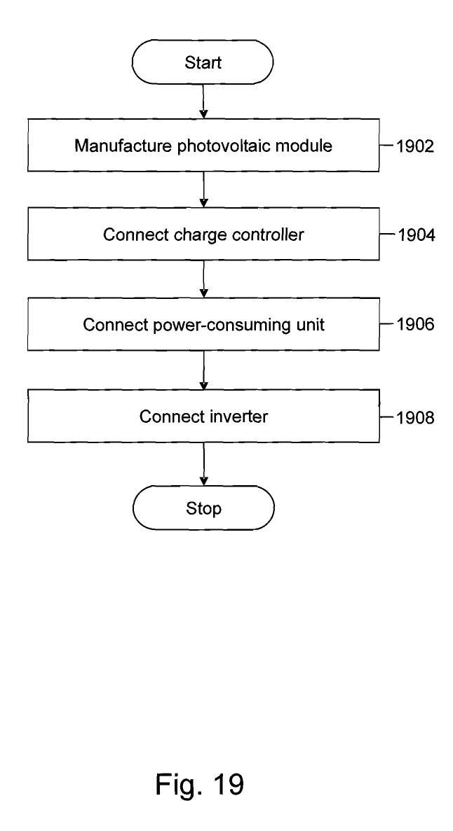

FIG. 19 illustrates a method for manufacturing a system for generating electricity from solar energy, in accordance with another embodiment of the present invention.

At step 1902, a photovoltaic module is manufactured as described in FIGS. 1, 2, 12, 13, 14, and 15A-D. The photovoltaic module may, for example, be photovoltaic module 100 or photovoltaic module 2102. At step 1904, a charge controller is connected with the photovoltaic module. At step 1906, a power-consuming unit is connected with the charge controller. As explained above, the charge controller controls the amount of charge stored in the power-consuming unit. For example, if the amount of charge stored in the power-consuming unit exceeds a first threshold, the charge controller discontinues further charging of the power-consuming unit. Similarly, if the amount of charge stored in the power-consuming unit falls below a second threshold, the charge controller reinitiates charging of the power-consuming unit. In an embodiment of the present invention, the first threshold and the second threshold lie between the maximum and the minimum capacity of the power-consuming unit.

The power-consuming unit provides the electricity in a first form. Devices that use the first form of electricity may directly be connected to the power-consuming unit. However, devices that use a second form of electricity, require that the first form be converted to the second form. At step 1908, an inverter is connected with the power-consuming unit. The inverter converts the electricity from the first form to the second form. Examples of the first form and the second form include DC and AC.

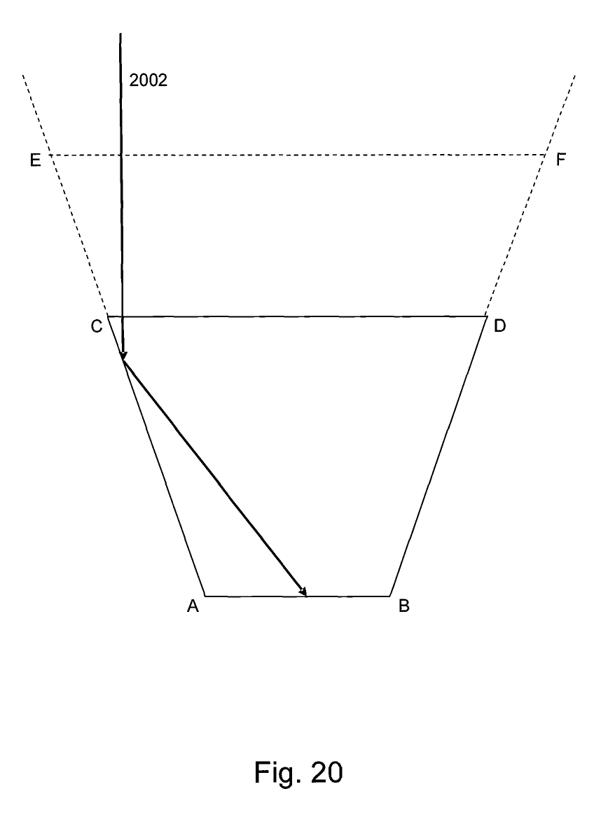

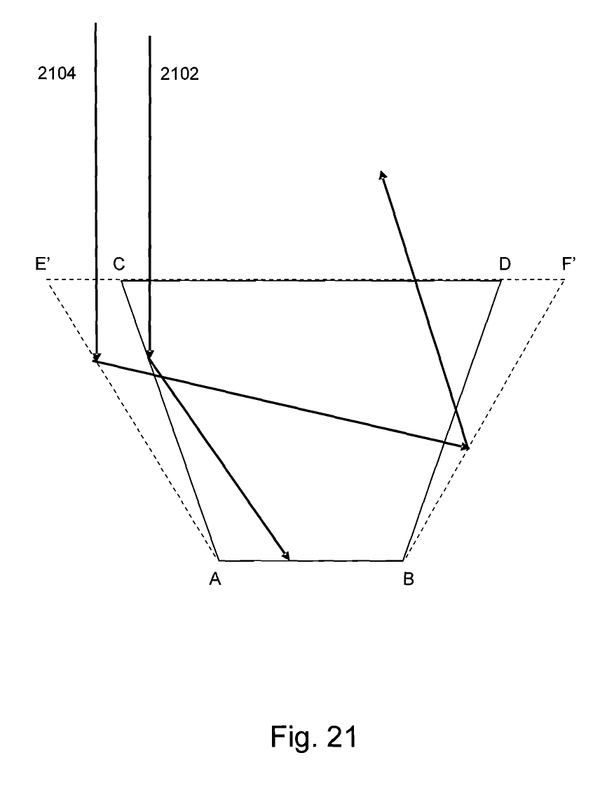

FIG. 20 illustrates how the level of concentration can be varied, in accordance with an embodiment of the present invention. AB represents an exit area through which rays exit, while CD represents a first entry area from where the rays enter. A first level of concentration is equal to the ratio of CD and AB. With reference to FIG. 20, the level of concentration is increased by increasing the height and the width of the empty area proportionally. EF represents a second entry area. A second level of concentration is equal to the ratio of EF and AB. The second level of concentration is greater than the first level of concentration, as EF is greater than CD.

In case of the first level of concentration, when a ray 2002 falls on side AC, it undergoes reflection towards AB as shown. In case of the second level of concentration, ray 2002 is reflected towards AB in the same manner.

FIG. 21 illustrates how the level of concentration can be varied, in accordance with an embodiment of the present invention. AB represents the exit area, while CD represents the first entry area. The first level of concentration is equal to the ratio of CD and AB. With reference to FIG. 21, the level of concentration is increased by increasing the width of the empty area without varying the height of the empty area. E′F′ represents a third entry area. A third level of concentration is numerically equal to the ratio of E′F′ and AB, and the third level of concentration is numerically greater than the first level of concentration, as E′F′ is greater than CD.

In case of the first level of concentration, when a ray 2102 falls on side AC, it undergoes reflection towards AB as shown. In case of the third level of concentration, when a ray 2104 falls on side AE′, it undergoes reflection towards BF′ as shown. Ray 1104 undergoes another reflection at BF′, and exits from E′F′. This leads to wastage of solar energy. Therefore, it can be concluded that the actual value of the third level of concentration is less than its numerical value.

It can be concluded that the acceptance angle of photovoltaic module 100 should be chosen appropriately. The acceptance angle is defined as the angle from the normal at which the power output from photovoltaic module 100 drops to a predefined value. The degree of acceptance angle varies with the geometry of the concentrator which in turn is dependent on the level of optical concentration. For example, the acceptance angel may vary when the concentration is varied between about 5:1 and 1.5:1.

Tracking mechanisms may be used to change the position of photovoltaic module 100, in order to keep the rays normally incident upon photovoltaic module 100 while the sun moves across the sky. This further enhances the power output of photovoltaic module 100.

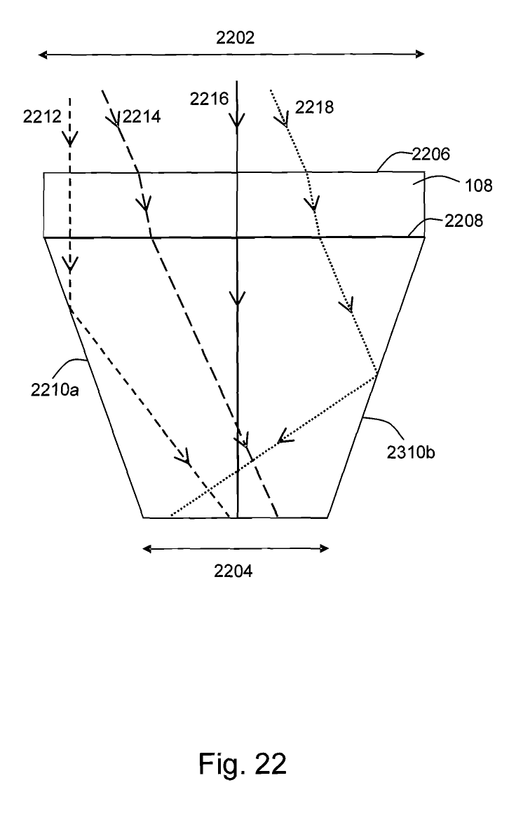

FIG. 22 is a cross-sectional view illustrating how electromagnetic radiation is concentrated over photovoltaic strips 104, in accordance with an embodiment of the present invention. A single low concentrator unit is shown. A portion of transparent member 108 over the empty space between two adjacent optical vees is shown. A photovoltaic strip (not shown in the figure) is placed between the two adjacent optical vees. The portion of transparent member 108 has an entry area 2202 through which rays enter, while the empty space has an exit area 2204, through which the rays exit towards the photovoltaic strip.

A medium boundary 2206 is formed between transparent member 108 and air. The refractive index of transparent member 108 is greater than the refractive index of air. Therefore, a ray passing from air to transparent member 108 is refracted towards the normal to medium boundary 2206, i.e., the angle of refraction is smaller than the angle of incidence.

A medium boundary 2208 is formed between transparent member 108 and air or vacuum in the empty space. The refractive index of transparent member 108 is greater than the refractive index of air or vacuum. Therefore, a ray passing from transparent member 108 to air is refracted away from the normal, i.e., the angle of refraction is greater than the angle of incidence.

With reference to FIG. 22, a ray 2212 is incident on medium boundary 2206 at an angle of incidence equal to zero. Ray 2212 passes through transparent member 108 and the empty area without any refraction. When incident on a side 2210a of an optical vee, ray 2212 undergoes reflection, and falls on the photovoltaic strip.

With reference to FIG. 22, a ray 2214 is incident on medium boundary 2206 at a non-zero angle of incidence. Ray 2214 refracts with a first angle of refraction smaller than its angle of incidence. When incident on medium boundary 2208, ray 2214 refracts again, with a second angle of refraction greater than its angle of incidence at medium boundary 2208, and falls on the photovoltaic strip.

With reference to FIG. 22, a ray 2216 is incident on medium boundary 2206 at an angle of incidence equal to zero. Ray 2216 passes through transparent member 108 and the empty area without any refraction, and falls on the photovoltaic strip.

With reference to FIG. 22, a ray 2218 is incident on medium boundary 2206 at a non-zero angle of incidence. Ray 2218 refracts with an angle of refraction smaller than its angle of incidence. When incident on medium boundary 2208, ray 2218 refracts again, with a second angle of refraction greater than its angle of incidence at medium boundary 2208. Further, when incident on a side 2210b of another optical vee, ray 2218 undergoes reflection, and falls on the photovoltaic strip.

FIG. 23 is a schematic diagram illustrating a configuration of one or more photovoltaic strips, in accordance with another embodiment of the present invention. With reference to FIG. 23, the photovoltaic strips are connected in series and parallel, such that the electrical output is maximized. In this configuration, three photovoltaic strips, such as a photovoltaic strip 2302a, a photovoltaic strip 2302b and a photovoltaic strip 2302c, are connected in series to form a first string. Similarly, a photovoltaic strip 2302d, a photovoltaic strip 2302e and a photovoltaic strip 2302f are connected in series to form a second string; a photovoltaic strip 2302g, a photovoltaic strip 2302h and a photovoltaic strip 2302i are connected in series to form a third string; a photovoltaic strip 2302j, a photovoltaic strip 2302k and a photovoltaic strip 2302l are connected in series to form a fourth string. These four strings are then combined in parallel.

It is to be understood that the specific designation for the configuration of photovoltaic strips in FIG. 23 is for the convenience of the reader and is not to be construed as limiting a photovoltaic module to a specific number or arrangement of its components.

The potential difference is directly proportional to the number of photovoltaic strips connected in series, while the current is directly proportional to the number of photovoltaic strips connected in parallel. The photovoltaic strips may be connected in series and parallel to create a configuration with a desired potential difference and current.

Table 1 is an exemplary table illustrating simulation data comparison between various types of photovoltaic modules, in accordance with an embodiment of the present invention.

TABLE 1

| Configuration | Unit | Concentration | Size (in mm) | Iₘ (in A) | Vₘ (in V) | Pₘ (in W) |
|---|---|---|---|---|---|---|
| 1 × 1 | Strip | 1:1 | 156 × 156 | 7.110 | 0.477 | 3.39 |
| 1 × 1 | Strip | 1:1 | 156 × 12 | 0.547 | 0.477 | 0.26 |
| 12 × 1 | Strip | 1:1 | 156 × 12 | 0.547 | 5.724 | 3.13 |
| 3(series) × | String | 1:1 | 156 × 12 × 12 | 2.188 | 17.172 | 37.57 |
| 4(parallel) | | | | | | |
| 3(series) × | String | 2:1 | 156 × 12 × 12 | 3.982 | 17.172 | 68.38 |
| 4(parallel) | | | | | | |
| 3(series) × | String | 3:1 | 156 × 12 × 12 | 5.973 | 17.172 | 102.568 |
| 4(parallel) | | | | | | |
| 3(series) × | String | 4:1 | 156 × 12 × 12 | 7.964 | 17.172 | 136.758 |
| 4(parallel) | | | | | | |
| 3(series) × | String | 5:1 | 156 × 12 × 12 | 9.955 | 17.172 | 170.954 |
| 4(parallel) | | | | | | |

With reference to Table 1,
‘Configuration’ denotes the configuration in which one or more photovoltaic strips are arranged to form a photovoltaic module;
‘Unit’ denotes the unit of the configuration;
‘Concentration’ denotes the level of concentration used in the photovoltaic module;
‘Size’ denotes the size of the photovoltaic strips used, in mm;
‘Im’ denotes the maximum current attained in the photovoltaic module, in ampere (A);
‘Vm’ denotes the maximum potential difference attained in the photovoltaic module, in volt (V); and
‘Pₘ’ denotes the maximum power developed in the photovoltaic module, in watt (W).

A first photovoltaic module has the configuration of ‘1×1’, the concentration of ‘1:1’ and the size of ‘156 mm×156 mm’. This implies that a single semiconductor wafer of size 156 mm×156 mm has been used without an additional concentrator.

The single semiconductor wafer is diced into 13 photovoltaic strips of size ‘156 mm×12 mm’ each. A second photovoltaic module is formed by a single photovoltaic strip of size 156 mm×12 mm without an additional concentrator.

A third photovoltaic module is formed by connecting 12 photovoltaic strips of size ‘156 mm×12 mm’ in series, without an additional concentrator. The 12 photovoltaic strips form one photovoltaic string.

A fourth photovoltaic module is formed by connecting three photovoltaic strings of size ‘156 mm×12 mm×12 nos.’ in series and combining four such configurations in parallel, without an additional concentrator. With reference to Table 1, the maximum current attained in the fourth photovoltaic module is four times the maximum current attained in the third photovoltaic module, while the maximum potential difference attained in the fourth photovoltaic module is thrice the maximum potential difference attained in the third photovoltaic module. Consequently, the maximum power developed in the fourth photovoltaic module is 12 times the maximum power developed in the third photovoltaic module.

A fifth photovoltaic module is formed by connecting three photovoltaic strings of size ‘156 mm×12 mm×12 nos.’ in series and combining four such configurations in parallel, with a concentrator providing a level of concentration of two. With reference to Table 1, the maximum current attained in the fifth photovoltaic module is nearly twice the maximum current attained in the fourth photovoltaic module. Consequently, the maximum power developed in the fifth photovoltaic module is nearly twice the maximum power developed in the fourth photovoltaic module.

A sixth photovoltaic module is formed by connecting three photovoltaic strings of size ‘156 mm×12 mm×12 nos.’ in series and combining four such configurations in parallel, with a concentrator providing a level of concentration of three. With reference to Table 1, the maximum current attained in the sixth photovoltaic module is nearly thrice the maximum current attained in the fourth photovoltaic module. Consequently, the maximum power developed in the sixth photovoltaic module is nearly thrice the maximum power developed in the fourth photovoltaic module.

A seventh photovoltaic module is formed by connecting three photovoltaic strings of size ‘156 mm×12 mm×12 nos.’ in series and combining four such configurations in parallel, with a concentrator providing a level of concentration of four. With reference to Table 1, the maximum current attained in the seventh photovoltaic module is nearly four times the maximum current attained in the fourth photovoltaic module. Consequently, the maximum power developed in the seventh photovoltaic module is nearly four times the maximum power developed in the fourth photovoltaic module.

A eighth photovoltaic module is formed by connecting three photovoltaic strings of size ‘156 mm×12 mm×12 nos.’ in series and combining four such configurations in parallel, with a concentrator providing a level of concentration of five. With reference to Table 1, the maximum current attained in the eighth photovoltaic module is nearly five times the maximum current attained in the fourth photovoltaic module. Consequently, the maximum power developed in the eighth photovoltaic module is nearly five times the maximum power developed in the fourth photovoltaic module. It should be appreciated that the maximum current attained and the maximum power developed in a photovoltaic module are directly proportional to the level of concentration provided in the photovoltaic module. As mentioned above, the level of concentration is measured by the ratio of the entry area and the exit area.

The comparison of various photovoltaic modules as described in Table 1 have been performed, based on IEC 61215 and IEC 62108.

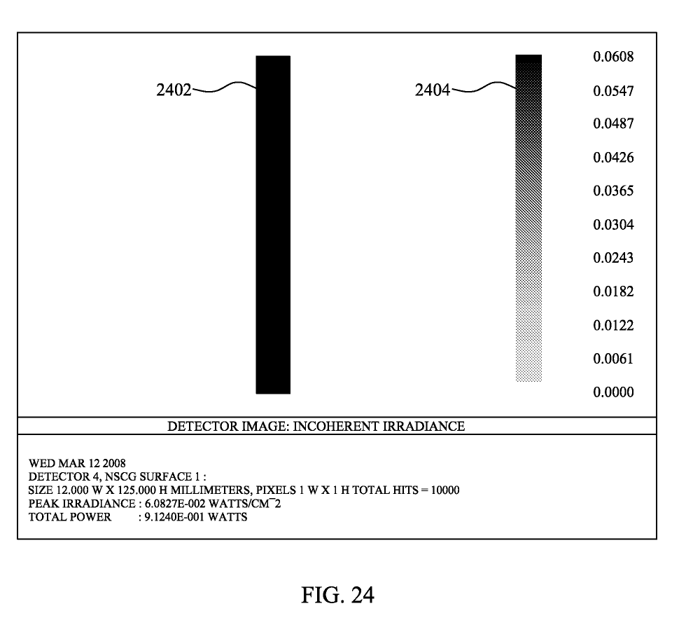

FIG. 24 illustrates a simulation of the output of a photovoltaic strip of size 125 mm×12 mm, in accordance with an embodiment of the present invention. An opaque rectangle 2402 denotes a detector, while a shaded rectangle 2404 denotes that the output is uniform from each part of the photovoltaic strip. The input irradiance over optical vees adjacent to the photovoltaic strip is 1 watt, while the power at the detector side is 0.912 watt. Therefore, the optical efficiency of the photovoltaic strip is 91.2%.

Embodiments of the present invention provide a photovoltaic module that is suitable for mass manufacturing, has lower cost, and is easy to manufacture compared to conventional low concentrator photovoltaic modules. The photovoltaic module has the same form factor as conventional low concentrator photovoltaic modules, and therefore, has no special mounting requirements In addition, the fabrication of the photovoltaic module involves the same processes as well as machines as required for fabricating conventional low concentrator photovoltaic modules.

In accordance with an exemplary embodiment of the present invention, the method for fabricating the photovoltaic module involves the use of plastic and aluminium for manufacture of various components. This makes the photovoltaic module cheaper and light-weight compared to conventional low concentrator photovoltaic modules.

Furthermore, the photovoltaic module provides maximized outputs, at appropriate configurations of the photovoltaic strips and appropriate levels of concentration. Moreover, the photovoltaic module is made of photovoltaic strips, which are arranged with spaces in between two adjacent photovoltaic strips. Therefore, the photovoltaic module requires lesser amount of semiconductor material to produce the same output, as compared to conventional low concentrator photovoltaic modules

This application may disclose several numerical range limitations that support any range within the disclosed numerical ranges even though a precise range limitation is not stated verbatim in the specification because the embodiments of the invention could be practiced throughout the disclosed numerical ranges. Finally, the entire disclosure of the patents and publications referred in this application, if any, are hereby incorporated herein in entirety by reference.

1. An apparatus for generating electricity from solar energy, said apparatus comprising:
a base substrate;
one or more photovoltaic strips arranged over said base substrate, wherein spaces are formed in between adjacent photovoltaic strips;
a plurality of optical vees for concentrating solar energy over said photovoltaic strips, said optical vees being placed in said spaces between said photovoltaic strips, said optical vees comprising a reflective layer or surface, such that rays incident on said reflective layer or surface are reflected towards said photovoltaic strips; and
a transparent member positioned over said optical vees,
wherein said base substrate, said photovoltaic strips, said optical vees and said transparent member form said apparatus in an integrated manner.

2. The apparatus of claim 1, wherein said photovoltaic strips are connected through one or more conductors in a predefined manner, said predefined manner is a series and/or parallel arrangement.

3. The apparatus of claim 1, wherein said optical vees comprise a molded polymeric material, and said reflective layer comprises a layer of a reflective material.

4. The apparatus of claim 1, wherein said optical vees comprise solid blocks of a reflective material.

5. The apparatus of claim 1, wherein said reflective surface comprises a polished sheet of a reflective material.

6. The apparatus of claim 1, wherein the reflective layer comprise a sandwiched foil comprising a foil of a reflective material between two sheets.

7. The apparatus of claim 1, wherein said optical vees comprise a reflection-enhancing layer to enhance the reflectivity of said optical vees.

8. The apparatus of claim 1, wherein said transparent member is sealed with said base substrate along a peripheral region of the base substrate.

9. The apparatus of claim 1, wherein said transparent member is coated with an anti-reflective coating to reduce loss of solar energy incident on said apparatus.

10. The apparatus of claim 1, wherein said optical vees are hollow.

11. The apparatus of claim 1, wherein said optical vees are solid.

12. The apparatus of claim 1, wherein said optical vees are made of a material selected from the group consisting of glass, a plastic, ethyl vinyl acetate (EVA), thermoplastic poly-urethane (TPU), poly vinyl butyral (PVB), a silicone, an acrylic, a polycarbonate, a metal, a metallic alloy, a metal compound and a ceramic.

13. An apparatus comprising:
supporting means for providing support to said apparatus;
converting means for converting solar energy into electrical energy, said converting means being arranged over said supporting means with spaces in between adjacent converting means;
concentrating means for concentrating solar energy over said converting means, said concentrating means being placed in said spaces between said converting means; and
transparent means for sealing said supporting means, said converting means and said concentrating means, said transparent means being positioned over said concentrating means,
wherein said supporting means, said converting means, said concentrating means and said transparent means form said apparatus in an integrated manner.

14. The apparatus of claim 13, wherein said concentrating means comprises a molded polymeric material, and said reflective layer comprises a reflective material deposited over said optical vees.

15. The apparatus of claim 13, wherein said concentrating means comprises solid blocks of a reflective material.

16. The apparatus of claim 13, wherein said reflective surface comprises a polished sheet of a reflective material.

17. A system for manufacturing a photovoltaic module, the system comprising:
a strip arranger for arranging one or more photovoltaic strips over a base substrate, wherein spaces are formed in between adjacent photovoltaic strips, said photovoltaic strips are capable of converting solar energy into electrical energy;
a stringer for connecting said photovoltaic strips through one or more conductors in a predefined manner;
an optical-vee placer for placing a plurality of optical vees in said spaces between said photovoltaic strips, said optical vees being capable of concentrating solar energy over said photovoltaic strips, said optical vees comprising a reflective layer or surface, such that rays incident on said reflective layer or surface are reflected towards said photovoltaic strips; and
a positioning unit for positioning a transparent member over said optical vees,
wherein said base substrate, said photovoltaic strips, said optical vees and said transparent member form said photovoltaic module in an integrated manner.

18. The system of claim 17 further comprising a dicer for dicing a semiconductor wafer to form said photovoltaic strips.

19. The system of claim 17 further comprising:
a molder for molding a polymeric material to form said optical vees; and
a depositor for depositing a reflective material over said optical vees to form said reflective layer.

20. The system of claim 17 further comprising:
a tool for machining solid blocks of a reflective material to form said optical vees; and
a polisher for polishing said solid blocks to form said reflective surface.

21-41. (canceled)
